(19) United States
(12) Patent Application Publication
(10) Pub. No.: US 2006/0147613 A1
(43) Pub. Date: Jul. 6, 2006

(54) Deposition system and method for measuring deposition thickness in the deposition system

(75) Inventors: Min Jeong Hwang, Suwon (KR); Sung Ho Lee, Yongin (KR)

Correspondence Address: H.C. PARK & ASSOCIATES, PLC, 8500 LEESBURG PIKE, SUITE 7500, VIENNA, VA, 22182, US

(73) Assignee: Samsung SDI Co., Ltd.

(21) Appl. No.: 11/325,310

(22) Filed: Jan. 5, 2006

(30) Foreign Application Priority Data
Jan. 5, 2005 (KR) 2005-0000968

(51) Int. Cl. C23C 14/54; B05C 11/00; C23C 16/00

(52) U.S. Cl. 427/9; 118/715; 118/726; 118/688

(57) ABSTRACT

A method of measuring a deposition thickness of a deposited material includes measuring an deposition rate of a material effused from an effusion cell using a sensor and calculating the deposition thickness of the material deposited on a substrate using a conversion formula that employs the measured deposition rate and the life value the time of use of the sensor as parameters.

### CROSS REFERENCE TO RELATED APPLICATIONS

This application claims priority to and the benefit of Korean Patent Application No. 2005-0000968, filed Jan. 5, 2005, which is hereby incorporated by reference for all purposes as if fully set forth herein.

### BACKGROUND

1. Field of the Invention

The present invention relates to a method of measuring the thickness of a material deposited on a substrate and a deposition system using the same, and more particularly, to a method of converting an effusion rate of an organic gaseous material effused from a deposition source into a deposition thickness on a substrate, and a deposition system using the same.

2. Discussion of the Background

Electroluminescent displays may be classified as inorganic electroluminescent displays or organic electroluminescent displays depending on the materials used for the emission layer. Organic electroluminescent displays are especially advantageous because they may be driven with a low voltage, may be lightweight and thin, may have a wide viewing angle, and may have a fast response time.

Organic electroluminescent displays may include an organic electroluminescent device having an anode, an organic material layer, and a cathode. The anode, organic material layer, and cathode may be stacked on a substrate. The organic material layer may include an organic emission layer that emits light. An electron injection layer and an electron transporting layer may be interposed between the cathode and the organic emission layer, and a hole injection layer and a hole transporting layer may be interposed between the anode and the organic emission layer.

Organic electroluminescent devices may be fabricated by a physical vapor deposition method or a chemical vapor deposition method. The physical vapor deposition method may be a vacuum deposition method, an ion plating method, a sputtering method, or the like. The chemical vapor deposition method may use a gas reaction. A vacuum deposition method has been used to deposit an organic gaseous material on a substrate by evaporating an organic material under vacuum. Vacuum deposition methods may employ an effusion cell to effuse the organic gaseous material evaporated in a vacuum chamber onto the substrate.

The organic gaseous material effused from the effusion cell may be deposited on the substrate to form an organic material layer. A sensor, such as a crystal (X-tal) sensor, may be placed near the substrate to measure the deposition rate of the organic gaseous material effused from the effusion cell. When the organic gaseous material is deposited on the crystal sensor, the frequency of the crystal sensor is changed. The change value of the crystal sensor's frequency is transmitted to a controller, which calculates the deposition thickness on the substrate based on the change value of the crystal sensor's frequency.

However, there may be a difference between the calculated deposition thickness and the actual deposition thickness because as the time of use of the crystal sensor increases, the accuracy of the calculated deposition thickness based on the frequency change of the crystal sensor decreases.

FIG. 1 shows the calculated deposition thickness of deposition samples measured by different crystal sensors A, B and C at various lengths of time of use of the sensors. The first crystal sensor A measures the deposition thickness of the organic layer formed on each deposition substrate 1108-4˜1109-3. The second crystal sensor B measures the deposition thickness of the organic layer formed on each deposition substrate 1109-4˜1109-7. It is recognized that the actual deposition thickness is gradually decreased as the measuring count, for example the life value is increased within the life span of the crystal sensor. The various actual deposition thicknesses of the organic gaseous material deposited on the substrate are actually gained by measuring at many position of the substrate with a measuring means. The terms ‘ave thick’ means the average value of the various actual deposition thicknesses.

FIG. 2 shows the calculated deposition thickness calculated from the frequency change of the crystal sensor over the life span of the crystal sensor. In FIG. 2, the terms ‘Cygnus Thick’ means the calculated deposition thickness. When one crystal sensor is used to measure the thickness of the organic material deposited on 11 substrates, it can be see that the calculated deposition thickness based on the frequency change of the crystal sensor remained slightly higher than about 1,000 Å, but the average value of the actual deposition thickness on the substrate decreased over the life span of the crystal sensor.

That is, soon after a new crystal sensor is actuated, the thickness of the organic material deposited on the first substrate 10-1 is calculated at about 1,000 Å and is also measured at about 1,000 Å. On the other hand, the thickness of the organic material deposited on the last substrate 10-11 is calculated at about 1,000 Å but it is actually measured at about 800 Å.

Therefore, it can be seen that as the life span of the crystal sensor used increases, the calculated deposition thickness based on the frequency change of the crystal sensor decreases. This makes it difficult to determine an accurate measurement of the deposition thickness.

Therefore, there exists a need for a method of accurately determining the deposition thickness using a crystal sensor.

### SUMMARY OF THE INVENTION

This invention provides a method of determining a deposition thickness on a substrate from an effusion rate of an organic gaseous material effused from an effusion cell measured by a sensor, and a deposition system using the same.

Additional features of the invention will be set forth in the description which follows, and in part will be apparent from the description, or may be learned by practice of the invention.

The present invention discloses a method of determining a deposition thickness in a deposition system, including measuring a deposition rate of a material effused from an effusion cell, the measuring being conducted by a sensor, transmitting the measured deposition rate to a controller, and calculating the deposition thickness of the material deposited on a substrate using a conversion formula that employs the measured deposition rate and the life value within the life span of the sensor as parameters.

The present invention also discloses a deposition system including a vacuum chamber, a substrate arranged in a first region of the vacuum chamber, an effusion cell arranged in a second region of the vacuum chamber and effusing a deposition material, an effusion rate measuring sensor measuring the deposition rate of the deposition material effused from the effusion cell, and a controller calculating the deposition thickness of the deposition material deposited on the substrate using a conversion formula that employs the measured deposition rate and the life value within the life span of the deposition rate measuring sensor as parameters.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a graph showing the change in deposition thicknesses corresponding to the life value within the life span of crystal sensors.

FIG. 2 is a graph showing the differences between calculated deposition thicknesses based on a deposition rate sensed by the crystal sensor and actual deposition thicknesses.

FIG. 3 illustrates a vacuum deposition system employing a crystal sensor for sensing the deposition rate.

FIG. 4 illustrates the vacuum deposition system in which an effusion cell is positioned in a film growth region.

FIG. 5 is a graph showing the difference between calculated deposition thicknesses based on the deposition rate sensed by the crystal sensor and actual deposition thicknesses according to an exemplary embodiment of the present invention.

FIG. 6 is a graph showing the calculated deposition thickness and the actual deposition thickness maintained about 1000 Å thickness according to the present invention.

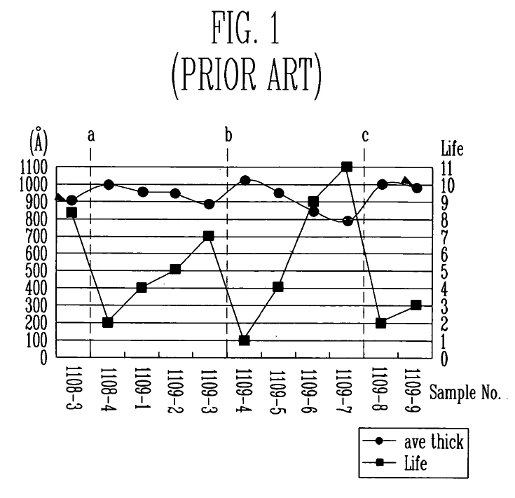

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity.

It will be understood that when an element such as a layer, film, region or substrate is referred to as being “on” another element, it can be directly on the other element or intervening elements may also be present. In contrast, when an element is referred to as being “directly on” another element, there are no intervening elements present.

Hereinafter, an “organic material” is defined as a material stored as a liquid or solid state in a furnace so as to form an organic material layer. An “organic gaseous material” is defined as a gaseous material obtained by evaporating the organic material when the furnace is heated.

According to an exemplary embodiment of the present invention, the deposition thickness of an organic material layer deposited on a substrate is calculated by a conversion formula employing the deposition rate of the organic gaseous material effused from the effusion cell and the life value within the life span of the crystal sensor as the parameters, so that the converted deposition thickness is approximately equal to the actual deposition thickness.

A vacuum deposition method may be used to form an organic material layer of an organic electroluminescent device in a vacuum deposition system that includes a vacuum chamber.

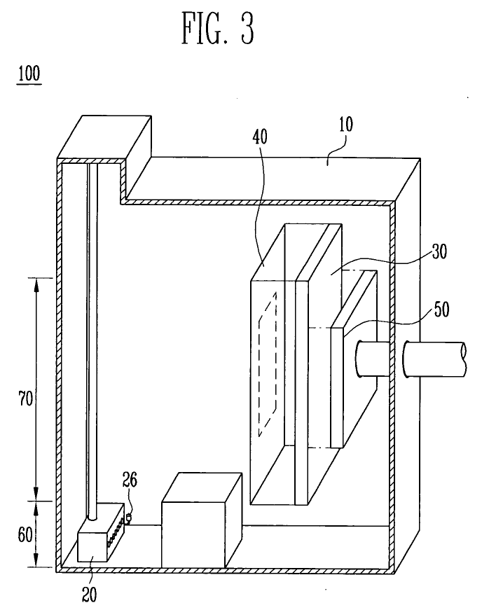

As shown in FIG. 3, a vacuum chamber 10 of a vacuum deposition system I 00 may accommodate therein a substrate 30 on which an organic material layer may be formed, a mask 40 placed in front of the substrate 30, and an effusion cell 20 arranged at a predetermined distance from the mask 40. The mask 40 may include a pattern forming part corresponding to a pattern of the organic material layer to be formed on the substrate 30, and a fixing part fixed to a mask frame.

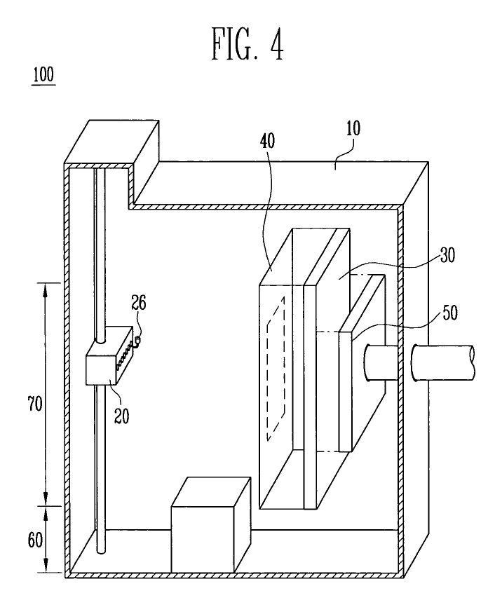

As shown in FIG. 4, the effusion cell 20 may move from a buffer region 60 of the vacuum chamber 10 after a preheating process and a deposition rate stabilizing process to a film growth region 70 of the vacuum chamber 10 by a vertical transporting means (not shown). In the film growth region 70, the effusion cell 20 effuses the organic gaseous material to form the organic material layer on the substrate 30.

The deposition rate of the organic gaseous material effused from the effusion cell 20 may be sensed by a sensor, such as a crystal sensor 26 placed in front of the effusion cell 20. When some organic gaseous material effused from the effusion cell 20 may be deposited on the crystal sensor 26, the frequency of the crystal sensor 26 is changing. The frequency change of the crystal sensor 26 may be transmitted as a signal to a controller (not shown). The controller may calculate the deposition thickness on the substrate using the signal and a conversion formula.

However, the measurement of the deposition rate due to the frequency change of the crystal sensor 26 may becomes less accurate as the life value within the life span of the crystal sensor used increases, so that the calculated deposition thickness may also becomes less accurate.

To obtain an accurate deposition thickness from the deposition rate of the organic gaseous material, the conversion formula may be compensated according to the life value of the crystal sensor. The compensated conversion formula may be as follows:
Deposition thickness=β−α×life value

Where, α and β are constant.

α and β may be chosen according to the type of organic material used, the target deposition rate, the desired thickness of the organic material layer to be formed on the substrate, the type of crystal sensor used, and the type of the vacuum deposition system used.

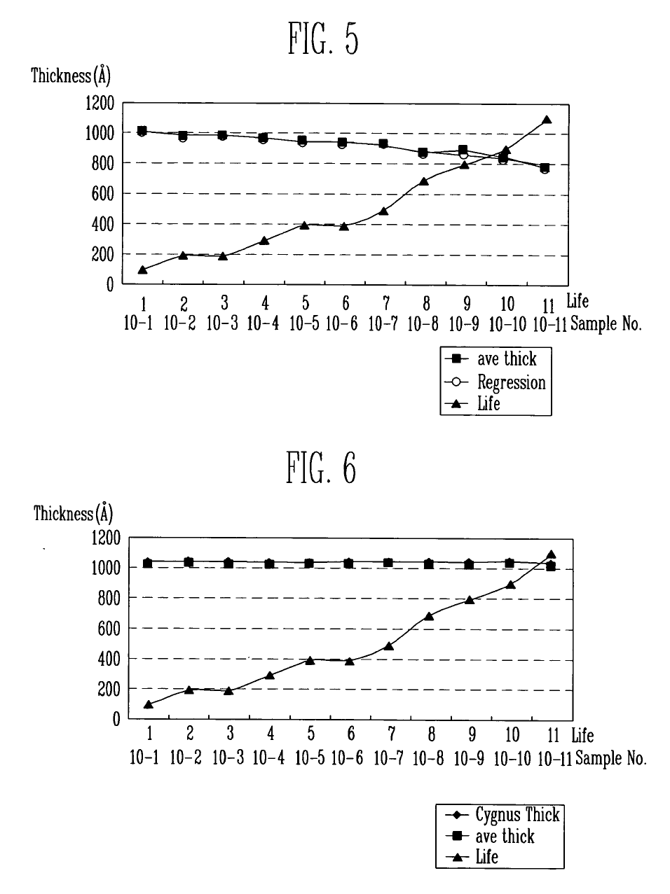

FIG. 5 shows the accuracy of the calculated deposition thickness calculated from the signal from a crystal sensor over the time of use of the crystal sensor using the compensated conversion formula according to an exemplary embodiment of the present invention. Referring to FIG. 5, it can be seen that the calculated deposition thickness based on the deposition rate due to the frequency change of the crystal sensor and the life value within the life span of the crystal sensor remained close to the actual measured deposition thickness over the time of use of the crystal sensor. In FIG. 5, the converted deposition thickness is obtained by the following formula:
Deposition thickness=1045−21.8×life value

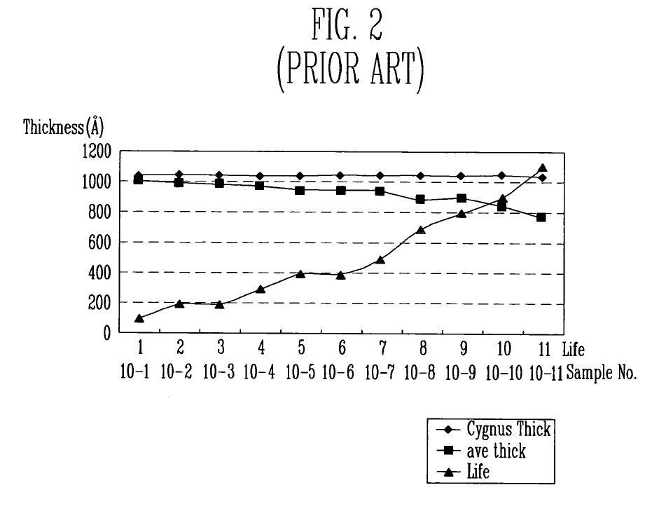

In FIG. 5, the converted deposition thickness indicated by the circle is converted from the calcaluted deposition thickness shown in FIG. 2 by applying the above formula. It is can be seen that the converted deposition thickness remains close to the actual measured deposition thickness indicated by the black square within the life span of the crystal sensor.

The controller may control the actuation of the effusion cell to increase the target deposition rate of the organic gaseous material as the life value of the crystal sensor increases. That is, the controller may increase the supply amount of the organic gaseous material effused from the effusion cell when the converted deposition thickness gained from the frequency change of the crystal sensor is lower than the target deposition thickness.

FIG. 6 shows the converted deposition thickness remaining about above 1000 Å that is similar to the target deposition thickness. The converted deposition thickness is gained by a conversion formula employing the deposition rate of the organic gaseous material and the life value of the crystal sensor according to the invention. The controller may control the actuation of the effusion cell to increase the supply amount of the organic gaseous material as the life value of the crystal sensor increases.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A method of determining a deposition thickness in a deposition system, comprising:
measuring an deposition rate of a material effused from an effusion cell, the measuring being conducted by a sensor;
transmitting the measured deposition rate to a controller; and
calculating the deposition thickness of the material deposited on a substrate using a conversion formula that employs the measured deposition rate and the life value of the sensor as parameters.

2. The method of claim 1,
wherein the life value is set within the life span of the sensor from the time when the sensor begins measuring the deposition rate to the time when the sensor stops measuring the deposition rate.

3. The method of claim 1,
wherein the sensor comprises a crystal sensor.

4. The method of claim 1,
wherein the conversion formula comprises the formula:
Deposition thickness=β−α×life value
where, α and β are constant.

5. The method of claim 4,
wherein α equals 21.8, and β equals 1045.

6. The method of claim 4,
wherein α and β are determined according to at least one of the factors of the group consisting of: a type of material effused from the effusion cell, a desired deposition rate, a desired deposition thickness, a type of sensor used, and a type of deposition system used.

7. A deposition system comprising:
a vacuum chamber;
a substrate arranged in a first region of the vacuum chamber;
an effusion cell arranged in a second region of the vacuum chamber and effusing a deposition material;
an effusion rate measuring sensor measuring the deposition rate of the deposition material effused from the effusion cell; and
a controller calculating the deposition thickness of the deposition material deposited on the substrate using a conversion formula that employs the measured deposition rate and the life value of the effusion rate measuring sensor as parameters.

8. The deposition system of claim 7,
wherein the life value is set within the life span of the effusion rate measuring sensor from the time when the effusion rate measuring sensor begins measuring the deposition rate to the time when the sensor stops measuring the deposition rate.

9. The deposition system of claim 7,
wherein the effusion rate measuring sensor comprises a crystal sensor.

10. The deposition system of claim 9,
wherein the crystal sensor is mounted to the effusion cell.

11. The deposition system of claim 7,
wherein the controller increases the effusion rate of the deposition material effused from the effusion cell as the life value of the effusion rate measuring sensor increases.

12. The deposition system of claim 7,
wherein the substrate is used for an organic electroluminescent device.

13. The deposition system of claim 7,
wherein the conversion formula comprises the formula:
Deposition thickness=β−α×life value
where, α and β are constant.

14. The deposition system of claim 13,
wherein a equals 21.8, and β equals 1045.

15. The deposition system of claim 13,
wherein α and β are determined according to at least one of the factors of the group consisting of: a type of material effused from the effusion cell, a desired deposition rate, a desired deposition thickness, a type of sensor used, and a type of deposition system used.
